(19) United States
(12) Patent Application Publication
(10) Pub. No.: US 2025/0031560 A1
(43) Pub. Date: Jan. 23, 2025

(54) APPARATUS OF MANUFACTURING COVER LAYER AND METHOD OF MANUFACTURING COVER LAYER USING THE SAME

(71) Applicant: Samsung Display Co., Ltd., Yongin-si (KR)

(72) Inventors: Junyoung LEE, Yongin-si (KR); Jeongweon SEO, Yongin-si (KR); Junwoo YOU, Yongin-si (KR); Sung-Woon IM, Yongin-si (KR)

(21) Appl. No.: 18/607,788

(22) Filed: Mar. 18, 2024

(30) Foreign Application Priority Data
Jul. 17, 2023 (KR) 10-2023-0092709

(51) Int. Cl. H10K 71/16; C23C 14/04; H10K 59/80

(52) U.S. Cl. CPC H10K 71/166; C23C 14/04; H10K 59/8792

(57) ABSTRACT

A cover layer manufacturing method includes: a first applying process, which forms a first cover layer on a rear surface of a first display panel using a first mask in an applying unit; a first cleaning process, which cleans a second mask in a cleaning unit; a rotating process, which changes a position of the first mask and a position of the second mask using a rotation driver; a second applying process, which forms a second cover layer on a rear surface of a second display panel using the second mask in the applying unit; and a second cleaning process, which cleans the first mask in the cleaning unit. The first applying process and the first cleaning process are substantially simultaneously performed, and the second applying process and the second cleaning process are substantially simultaneously performed.

This application claims priority to Korean Patent Application No. 10-2023-0092709, filed on Jul. 17, 2023, and all the benefits accruing therefrom under 35 U.S.C. § 119, the content of which in its entirety is herein incorporated by reference.

### BACKGROUND

### 1. Field of Disclosure

The present disclosure relates to an apparatus of manufacturing a cover layer and a method of manufacturing the cover layer using the apparatus.

### 2. Description of the Related Art

An organic light emitting diode display (“OLED”) is being spotlighted as a next generation flat display device for its excellent brightness and viewing angle. Since the organic light emitting diode display does not need a separate light source, it is manufactured with a thin thickness and a light weight. In addition, the organic light emitting diode display has properties, such as low power consumption, high brightness, fast response speed, etc.

The organic light emitting diode display includes a display panel. When the display panel is manufactured, various layers, such as a light emitting layer, an electrode layer, an encapsulation layer, etc., are formed. Accordingly, various display panels are manufactured using a mask in which an opened area and a closed area are defined.

However, an organic material, such as a resin, used in an applying process using a mask remains on a bridge portion of the mask. In a case where the resin remains on a rear surface of the mask, the resin disturbs the contact between the mask and a mother substrate or a portion of the resin falls on the mother substrate, and thus, the reliability of the display device is deteriorated. Accordingly, the mask used in the applying process is cleaned to remove the resin remaining on the bridge portion of the mask between the applying process and the next applying process. However, when the cleaning process is performed between the applying processes, the applying processes are not able to be performed continuously.

### SUMMARY

The present disclosure provides an apparatus of manufacturing a cover layer, which is capable of substantially simultaneously carrying out an applying process and a cleaning process using different masks from each other.

The present disclosure provides a method of manufacturing the cover layer using the apparatus to improve a process yield and reduce a process time.

Embodiments of the invention provide a method of manufacturing a cover layer. The manufacturing method of the cover layer includes: a first applying process, which forms a first cover layer on a rear surface of a mother substrate using a first mask in an applying unit; a first cleaning process, which cleans a second mask in a cleaning unit; a rotating process, which changes a position of the first mask and a position of the second mask using a rotation driver; a second applying process, which forms a second cover layer on a rear surface of another mother substrate using the second mask in the applying unit; and a second cleaning process, which cleans the first mask in the cleaning unit. The first applying process and the first cleaning process are substantially simultaneously performed, and the second applying process and the second cleaning process are substantially simultaneously performed.

The applying unit may include: a panel stage, a mask stage disposed on the panel stage, a squeeze disposed on the first mask, and a resin stage disposed at one side of the mask stage, the first mask may be provided with a first mask opening defined therethrough to expose the rear surface of the first display panel, and the first applying process may include: placing the first mask on the mask stage, applying a resin on one side of the first mask, and a first squeezing process, which moves the squeeze in a direction from the one side of the first mask toward the resin stage to place the resin in the first mask opening.

The method may further include: a remaining resin removing process, which moves the squeeze in the direction from the one side of the first mask toward the resin stage to remove a remaining resin disposed on an upper surface of the first mask after the first squeezing process.

The method may further includes: an additional squeezing process, which moves the squeeze in a direction from the resin stage toward the one side of the first mask to rearrange a stage resin collected on the resin stage in the first mask opening after the first squeezing process.

The second mask may be provided with a second mask opening defined therethrough to expose the rear surface of the another mask substrate, and the second applying process may include: placing the second mask on the mask stage, applying a resin on one side of the second mask, and a second squeezing process, which moves the squeeze in a direction from the one side of the second mask toward the resin stage to place the resin in the second mask opening.

The cleaning unit may include a bath accommodating a cleaning solution and an ultrasonic generator disposed in the bath and generating an ultrasonic wave in the bath.

The first cleaning process may further include: a first immersing process, which immerses the second mask into the cleaning solution; a first ultrasonic cleaning process, which cleans the second mask using the ultrasonic wave; and a first taking-out process, which takes the second mask out of the cleaning solution, and the second cleaning process may further include: a second immersing process, which immerses the first mask into the cleaning solution; a second ultrasonic cleaning process, which cleans the first mask using the ultrasonic wave; and a second taking-out process, which takes the first mask out of the cleaning solution.

The cleaning unit may further include at least one brush disposed in the bath and rotating in a predetermined direction, the first cleaning process may further include rotating the at least one brush to clean the second mask, and the second cleaning process may further include rotating the at least one brush to clean the first mask.

The at least one brush may be disposed spaced apart from the second mask in an opening defined through the second mask in the first cleaning process, the second mask may be cleaned by a whirlpool of the cleaning solution, which is generated by the rotation of the at least one brush in the first cleaning process, the at least one brush may be disposed spaced apart from the first mask in an opening defined through the first mask in the second cleaning process, and the first mask may be cleaned by a whirlpool of the cleaning solution, which is generated by the rotation of the at least one brush in the second cleaning process.

Embodiments of the invention provide a method of manufacturing a cover layer. The manufacturing method of the cover layer includes: a first applying process, which forms a first cover layer on a rear surface of a first display panel using a first mask in an applying unit; a first standby process in which a second mask used in the applying unit prior to the first applying process is on standby in a first standby unit, a first cleaning process, which cleans a third mask in a cleaning unit; a second standby process in which a fourth mask cleaned in the cleaning unit prior to the first cleaning process is on standby in a second standby unit; and a rotating process, which changes a position of the first mask, a position of the second mask, a position of the third mask, and a position of the fourth mask using a rotation driver.

The first applying process and the first cleaning process are substantially simultaneously performed.

After the rotating process, the first mask may be placed in the first standby unit, and the third mask is placed in the second standby unit.

The method may further include: a second applying process, which forms a second cover layer on a rear surface of a second display panel using the fourth mask in the applying unit after the rotating process; and a second cleaning process, which cleans the second mask using the cleaning unit after the rotating process, and the second applying process and the second cleaning process may be substantially simultaneously performed.

Embodiments of the invention provide an apparatus of manufacturing a cover layer including: an applying unit including a panel stage and a mask stage disposed on the panel stage, wherein a mother substrate is disposed in an opening of the mask stage and a front surface of the mother substrate faces the panel stage; a cleaning unit including a bath configured to accommodate a cleaning solution and an ultrasonic generator configured to generate an ultrasonic wave in the cleaning solution; a first mask disposed on the mask stage; a second mask disposed in the bath; and a rotation driver.

Here, the applying unit is configured to form a cover layer on a rear surface of the first display panel using the first mask, the second mask is configured to be cleaned in the cleaning unit while the cover layer is formed, and the first mask and the second mask are each provided with an opening defined therethrough.

The apparatus further may include a standby unit in which a mask used in the applying unit or a mask cleaned in the cleaning unit is on standby.

The applying unit, the cleaning unit, the standby unit, the first mask, the second mask, and the mask in the standby unit may each be provided one or more, and a total number of the first mask, the second mask, and the mask in the standby unit may be equal to a total number of the applying unit, the cleaning unit, and the standby unit.

The applying unit may further include a resin stage and a squeeze.

The cover layer may include a light-absorbing material.

The apparatus may further include at least one brush disposed in the bath, and the at least one brush may rotate to generate a whirlpool in the cleaning solution.

The at least one brush may be spaced apart from an inner side surface of the mask, which defines the opening of the second mask.

The rotation driver may be connected to each of the first mask and the second mask by a connector.

According to the above, the process of applying the resin to the display panel and the process of cleaning the mask to be used in a next resin applying process are substantially simultaneously performed using a plurality of masks, and thus, several applying processes are carried out continuously and sequentially in time, thereby effectively increasing the speed of the total process and increasing a mass production of the cover layer.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a perspective view of a display device according to an embodiment of the present disclosure;

FIG. 2 is a cross-sectional view of a portion of the display device taken along line I-I′ of FIG. 1;

FIG. 3A is a view schematically illustrating an apparatus of manufacturing a cover layer according to an embodiment of the present disclosure;

FIG. 3B is a perspective view of an applying unit according to an embodiment of the present disclosure;

FIG. 3C is a cross-sectional view of a cleaning unit according to an embodiment of the present disclosure;

FIGS. 4A and 4B are cross-sectional views illustrating a process of placing a first mask on a mask stage according to an embodiment of the present disclosure;

FIGS. 5A to 5C are perspective views illustrating a first squeezing process according to an embodiment of the present disclosure;

FIGS. 6A to 6D are views illustrating a processing of removing a remaining resin according to an embodiment of the present disclosure;

FIGS. 7A and 7B are cross-sectional views illustrating a process of separating a first mask from an applying unit after a first applying process is finished;

FIGS. 8A to 8C are cross-sectional views illustrating a first cleaning process according to an embodiment of the present disclosure;

FIGS. 9A and 9B are views schematically illustrating a rotating process according to an embodiment of the present disclosure;

FIG. 10A is a view schematically illustrating a cover layer manufacturing apparatus which includes four masks according to an embodiment of the present disclosure; and

FIG. 10B is a view schematically illustrating a cover layer manufacturing apparatus which includes eight masks according to an embodiment of the present disclosure.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, a method of manufacturing a cover layer and an apparatus of manufacturing the cover layer according to embodiments of the present disclosure will be described with reference to accompanying drawings.

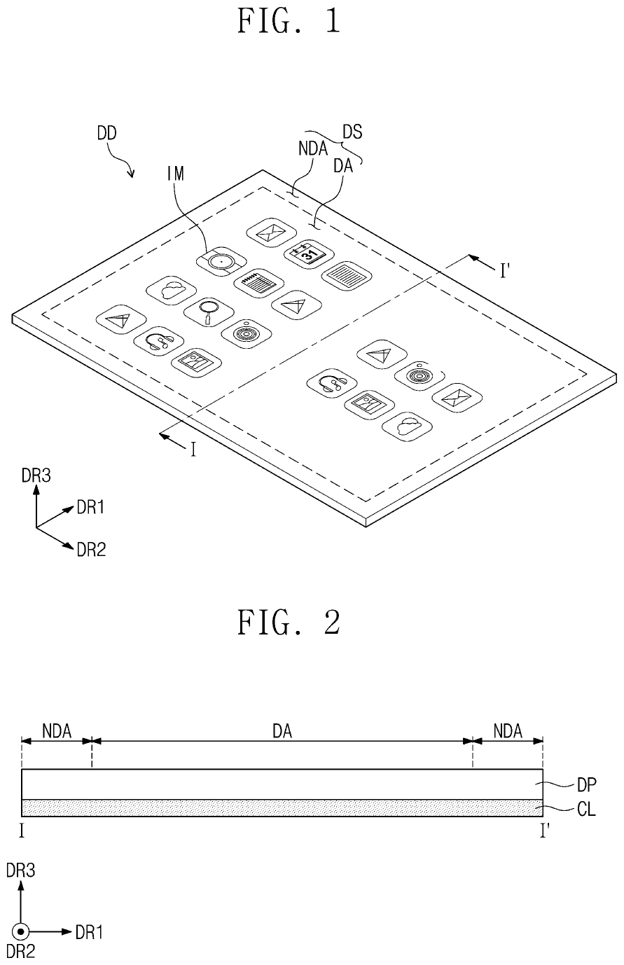

FIG. 1 is a perspective view of a display device DD according to an embodiment of the present disclosure. FIG. 2 is a cross-sectional view of a portion of the display device DD taken along line I-I′ of FIG. 1.

The display device DD may be activated in response to electrical signals. The display device DD may include various embodiments. As an example, the display device DD may be applied to a large-sized electronic item, such as a television set, an outdoor billboard, etc., and a small and medium-sized electronic item, such as a mobile phone, a tablet computer, a navigation unit, a game unit, etc. However, these are merely examples, and the display device DD may be applied to other electronic devices as long as they do not depart from the concept of the present disclosure.

The display device DD may be flexible. The term “flexible” used herein refers to the property of being able to be bent from a structure that is completely bent to a structure that is bent at the scale of a few nanometers. For example, the display device DD may be a curved display device or a foldable display device. According to an embodiment, the display device DD may be rigid.

The display device DD may include a display surface to display an image IM through to a front surface of the display device DD. The display device DD may display the image IM through the display surface, which is substantially parallel to a plane defined by a first direction DR1 and a second direction DR2, toward a third direction DR3. The third direction DR3 may intersect each of the first direction DR1 and the second direction DR2, and a normal line direction of the display surface may be substantially parallel to the third direction DR3. The image IM displayed through the display surface may include a still image as well as a video.

According to an embodiment of the present disclosure, a process of applying a resin to a display panel and a process of cleaning a mask that is to be used in a next resin applying process are substantially simultaneously performed using multiple masks, and thus, several applying processes may be performed continuously and sequentially in time, thereby increasing a mass production of substrates.

In the present embodiment, front (or upper) and rear (or lower) surfaces of each component of the display device DD may be defined with respect to a direction in which the image IM is displayed. The front and rear surfaces may be opposite to each other in the third direction DR3. In an embodiment, a front (or upper) surface of a display panel DP (See FIG. 2) is a surface in which the image IM is displayed. Meanwhile, directions indicated by the first, second, and third directions DR1, DR2, and DR3 are relative to each other, and thus, the directions indicated by the first, second, and third directions DR1, DR2, and DR3 may be changed to other directions.

Referring to FIG. 2, the display device DD may include a display panel DP and a cover layer CL.

The display panel DP may be disposed on an upper surface of the cover layer CL. The display panel DP may display the image IM in response to electrical signals. According to an embodiment, the display panel DP may be a light emitting type display panel, however, it should not be particularly limited. For example, the display panel DP may be an organic light emitting display panel, an inorganic light emitting display panel, or a quantum-dot light emitting display panel.

The display panel DP may include a base layer, a circuit element layer disposed on the base layer and including at least one transistor, a display element layer including a light emitting element connected to the transistor, and an encapsulation layer covering the display element layer. In addition, the display panel DP may further include a panel protective layer disposed on a lower surface of the base layer, and it should not be particularly limited.

The display panel DP may include a display area DA and a peripheral area NDA. As pixels (not shown) are arranged in the display area DA and the pixels (not shown) emit lights in response to electrical signals, the display panel DP may display the image IM in the display area DA.

The peripheral area NDA may be defined adjacent to the display area DA. As an example, the peripheral area NDA may surround the display area DA when viewed in the plane. A driving circuit or a driving line may be disposed in the peripheral area NDA to drive the pixels (not shown) arranged in the display area DA.

The cover layer CL may be disposed on the rear surface of the display panel DP. The cover layer CL may block a light traveling in the third direction DR3 toward the cover layer CL from under the cover layer CL.

The cover layer CL may include a resin containing a light-absorbing material. As an example, the resin may include a synthetic resin and a filler. The filler may include the light-absorbing material such as a carbon fiber, a graphite, etc. As the resin includes the filler, the resin may have high thixotropy.

The thixotropy is a phenomenon exhibited by some fluids which have a gel-like consistency with no fluidity when the some fluids are stationary, the gel is liquefied and thus changed to a sol when stirred or shaken, and the sol returns to the gel with no fluidity when no shear stress is applied.

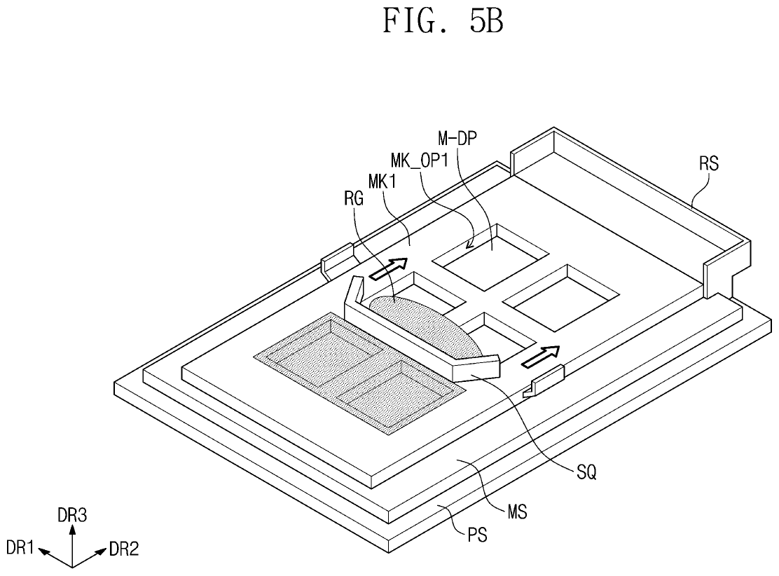

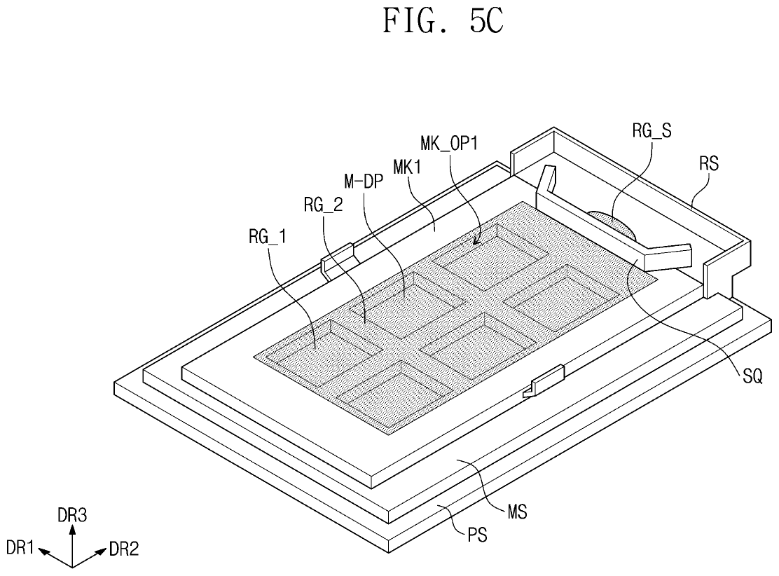

As described later, according to the present disclosure, since the applying process is performed using a resin RG (refer to FIG. 5A), which contains a large amount of the filler and has high thixotropy, a layer with thick thickness may be formed. In addition, since the multiple masks are cleaned regularly, it is also advantageous from a maintenance perspective.

As the cover layer CL is formed on the rear surface of the display panel DP, the cover layer CL may block the light traveling in the third direction DR3 toward the cover layer CL from under the cover layer CL.

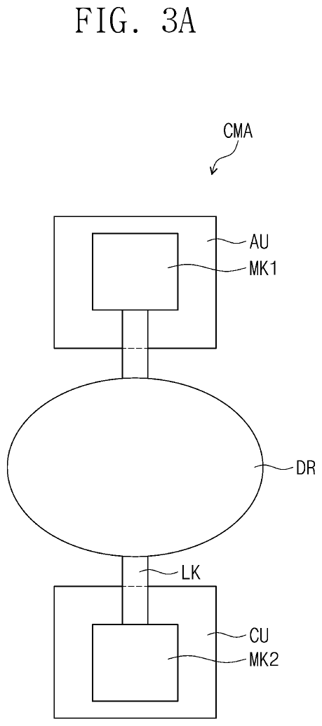

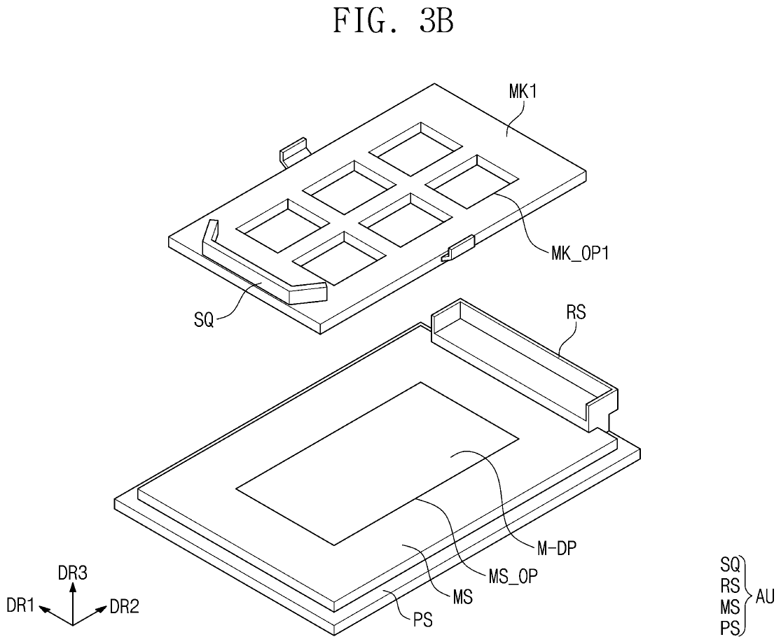

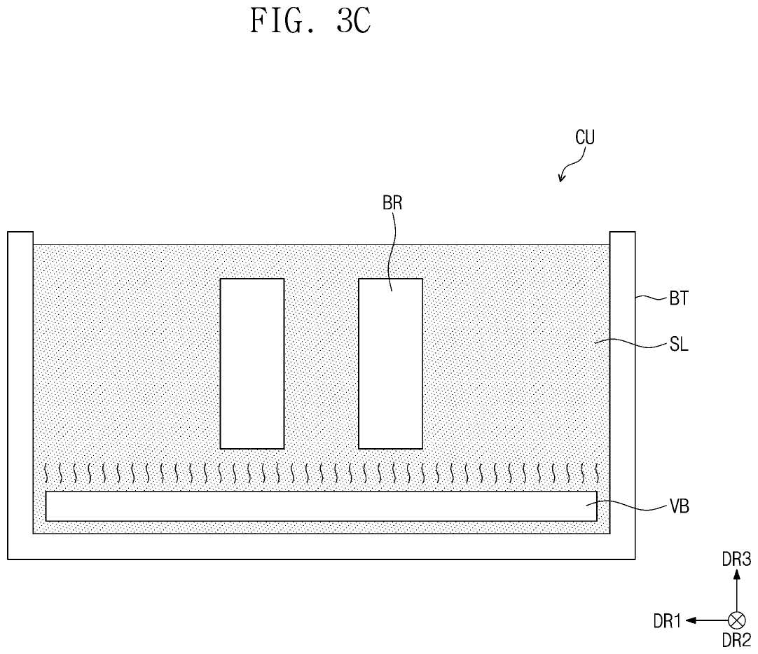

Hereinafter, an apparatus CMA of manufacturing the cover layer CL (hereinafter, referred to as a cover layer manufacturing apparatus) will be described in detail with reference to FIGS. 3A to 3C.

FIG. 3A is a view schematically illustrating the cover layer manufacturing apparatus CMA according to an embodiment of the present disclosure. FIG. 3B is a perspective view of an applying unit AU according to an embodiment of the present disclosure. FIG. 3C is a cross-sectional view of a cleaning unit CU according to an embodiment of the present disclosure.

Referring to FIG. 3A, the cover layer manufacturing apparatus CMA may include the applying unit AU, a first mask MK1, a rotation driver DR, a second mask MK2, and the cleaning unit CU. The rotation driver DR may include a connector LK connected to corresponding masks MK1 and MK2.

The applying unit AU may be used to form the cover layer CL on a rear surface of a mother substrate M-DP using the first mask MK1. The mother substrate M-DP may correspond to the display panels DP of FIG. 2 before being cut into individual display panels.

The cleaning unit CU may be used to clean the second mask MK2 used to form the cover layer CL using the applying unit AU.

The rotation driver DR may be used to change positions of the first mask MK1 and the second mask MK2. As an example, the first mask MK1 used in the applying unit AU and the second mask MK2 cleaned in the cleaning process in the cleaning unit CU may be connected to the connector LK, and then, positions thereof may be changed to each other. Accordingly, the second mask MK2 may be located in the applying unit AU, and the first mask MK1 may be located in the cleaning unit CU.

The rotation driver DR may further include a motor that provides a power to the connector LK. The connector LK should not be particularly limited as long as the connector LK, such as a robot arm, changes the position of the first mask MK1 and the position of the second mask MK2.

Referring to FIG. 3B, the applying unit AU may include a mask stage MS, a panel stage PS, a squeeze SQ, and a resin stage RS.

The panel stage PS may have a flat shape. The panel stage PS may provide a plate on which other components included in the applying unit AU are arranged.

The mask stage MS may be disposed on the panel stage PS. The first mask MK1 may be stably disposed on the mask stage MS, and a mask stage opening MS_OP in which the mother substrate M-DP is disposed may be defined in the mask stage MS.

When the mother substrate M-DP is inserted into the mask stage opening MS_OP, a movement of the mother substrate M-DP in the first direction DR1 and the second direction DR2 may be reduced. Accordingly, the movement of the mother substrate M-DP may be reduced in the applying process described later. In addition, the first mask MK1 may be disposed on an upper surface of the mask stage MS. The upper surface of the mask stage MS may be flat to place the first mask MK1 thereon, and face the third direction DR3. In this embodiment, the mother substrate M-DP is disposed upside down. Therefore, the cover layer CL may be formed on a rear surface of a mother substrate M-DP, which face the first mask MK1.

The first mask MK1 may be a mask used to form the cover layer CL described with reference to FIG. 2. The first mask MK1 may be provided with a first mask opening MK_OP1 defined therethrough.

FIG. 3B shows six first mask openings MK_OP1 arranged in a two-by-three (2×3) arrangement as a representative example. The first mask openings MK_OP1 may be arranged in an n-by-m (n×m) arrangement where each of “n” and “m” may be a natural number, and they should not be limited thereto or thereby.

The mother substrate M-DP may include the display panel DP provided in a number corresponding to the number of the first mask openings MK_OP1. Accordingly, six display panels DP may be formed by cutting the mother substrate M-DP shown in FIG. 3B.

The resin stage RS may be disposed at one side of the mask stage MS. The squeeze SQ may be disposed on the first mask MK1. The squeeze SQ may move back and forth along the second direction DR2 on the first mask MK1 by a motor.

The resin used to form the cover layer CL may be filled in the first mask opening MK_OP1 by the squeeze SQ. As an example, the squeeze SQ may move the resin (See RG in FIG. 5A) applied to one side of the first mask MK1 in the second direction DR2, and thus, the resin may be gradually filled in corresponding first mask openings MK_OP1. The resin pushed to the other side of the first mask MK1 along the second direction DR2 may be stored in the resin stage RS, and the resin stored in resin stage RS may be reused by the squeeze SQ. This will be described in detail later. Referring to FIG. 3C, the cleaning unit CU may include a bath BT, a cleaning solution SL, an ultrasonic generator VB, and a brush BR.

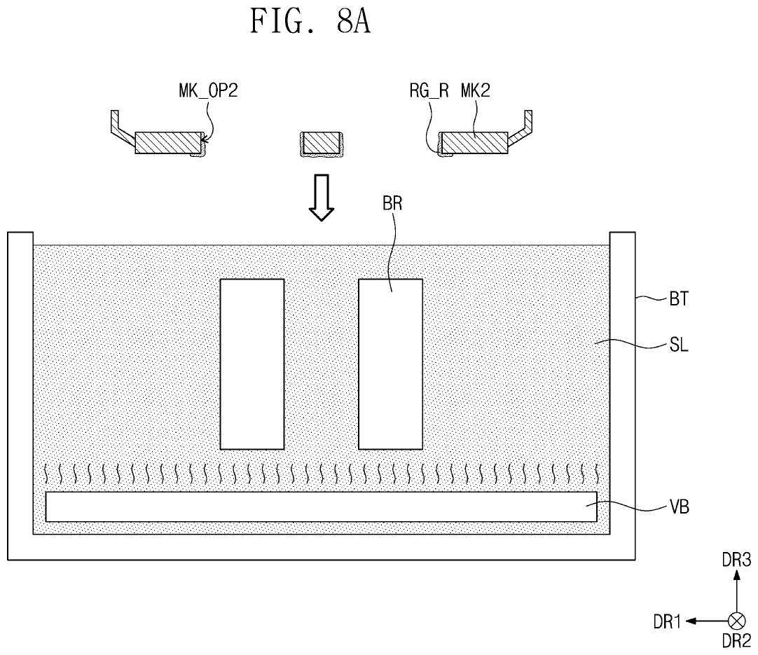

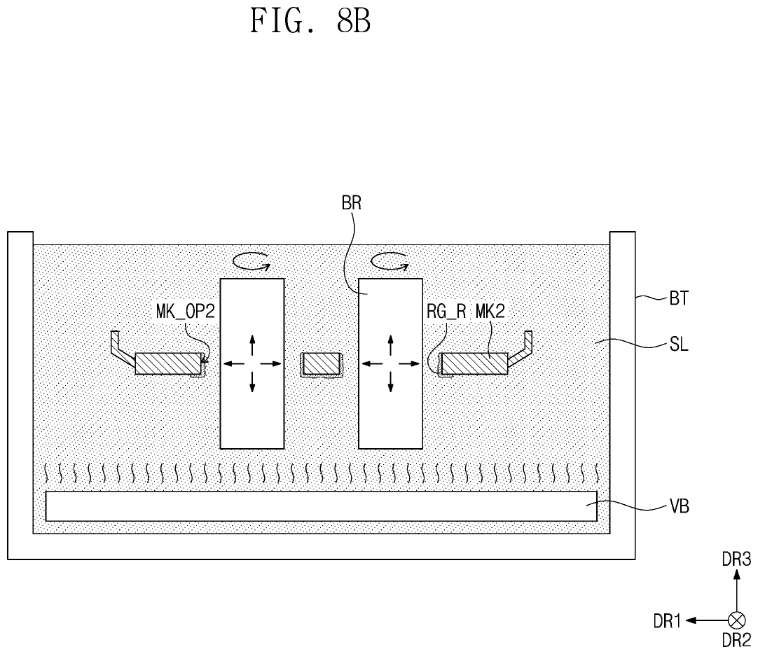

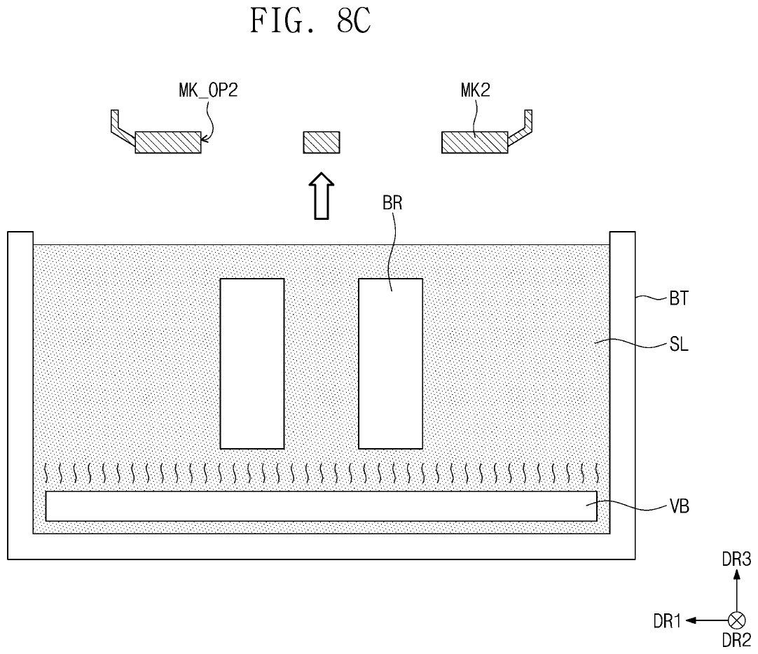

The cleaning unit CU may be used to clean a remaining resin (See RG_R in FIG. 8A) remaining on the mask. The remaining resin may be the resin used in the applying process that forms the cover layer CL (refer to FIG. 2) and remaining on the mask. In the case of the first mask MK1 described with reference to FIG. 3B, the remaining resin may remain on at least one of an inner side surface, which defines the first mask opening MK_OP1, an upper surface adjacent to the inner side surface, and a lower surface adjacent to the inner side surface of the first mask MK1.

The bath BT may provide an inner space in which the cleaning solution SL is accommodated. An upper surface of the bath BT may be opened so that the mask used in the applying process may be loaded and unloaded. As an example, the bath BT may include a bottom surface substantially parallel to the first direction DR1 and the second direction DR2 and a side surface extending from the bottom surface to the third direction DR3. The upper surface opposite to the bottom surface in the third direction DR3 may be opened. Accordingly, the cleaning solution SL may be accommodated in the bath BT.

However, this is merely an example, and the shape of the bath BT should not be particularly limited as long as the bath BT includes an opened area to allow the first mask MK1 to be immersed in the cleaning solution SL and has a structure in which the cleaning solution SL is accommodated and does not flow outward.

The cleaning solution SL may be used to clean the residual resin remaining on the mask used in the applying process. The cleaning solution SL may be disposed in the bath BT, and the mask used in the applying process may be immersed in the cleaning solution SL. The cleaning solution SL may include a material that dissolves the resin used to form the cover layer CL (refer to FIG. 2) in the applying process. As an example, the cleaning solution SL may include at least one of N-Methyl-2-pyrrolidone (“NMP”) and an acidic substance that dissolves an organic material.

The ultrasonic generator VB and the brush BR may be disposed in the bath BT.

The ultrasonic generator VB may be disposed on one surface of the bath BT. The ultrasonic generator VB may generate ultrasonic waves by generating vibration. The ultrasonic generator VB may apply the vibration to the cleaning solution SL when applied with electricity. The cleaning solution SL may be vibrated, and thus, impacts may be applied to the resin RG remaining on the second mask MK2. FIG. 3C shows the structure in which the ultrasonic generator VB is disposed on the bottom surface of the bath BT as a representative example, however, the present disclosure should not be limited thereto or thereby. According to an embodiment, the ultrasonic generator VB may be disposed on the side surface of the bath BT.

The brush BR may be placed in the bath BT and may rotate to create a whirlpool of the cleaning solution SL around the brush BR. As an example, the brush BR may have a roll shape. The brush BR may be fixed to the bath BT by an axis extending in the third direction DR3, and a rotational movement of the brush BR may be controlled by a separate motor.

When the brush BR rotates, the cleaning solution SL may swirl and may apply impacts to the resin RG remaining on the mask. Due to the impacts, the resin RG may be separated from the mask or a gap may occur in the resin RG to allow the cleaning solution SL to permeate into the resin RG more easily. Accordingly, the resin RG remaining on the mask immersed into the cleaning solution SL may be effectively cleaned.

The cleaning unit CU according to the present disclosure may firstly clean the mask used in the applying process using the ultrasonic waves generated by the ultrasonic generator VB and may secondly clean the mask used in the applying process using the whirlpool of the cleaning solution SL generated by the brush BR, and thus, the mask used in the applying process may be able to be reused.

According to the present disclosure, the process of cleaning one mask used in the applying process may be performed in the cleaning unit CU while the applying process is performed on another mask using the applying unit AU. This will be described later.

The method of manufacturing the cover layer (hereinafter, referred to as a cover layer manufacturing method) may include a first applying process, a first cleaning process, a rotating process, a second applying process, and a second cleaning process. The first applying process and the second applying process may be performed in the above-described applying unit AU, and the first cleaning process and the second cleaning process may be performed in the above-described cleaning unit CU.

According to the present disclosure, the first applying process and the first cleaning process may be substantially simultaneously performed in the cover layer manufacturing apparatus CMA.

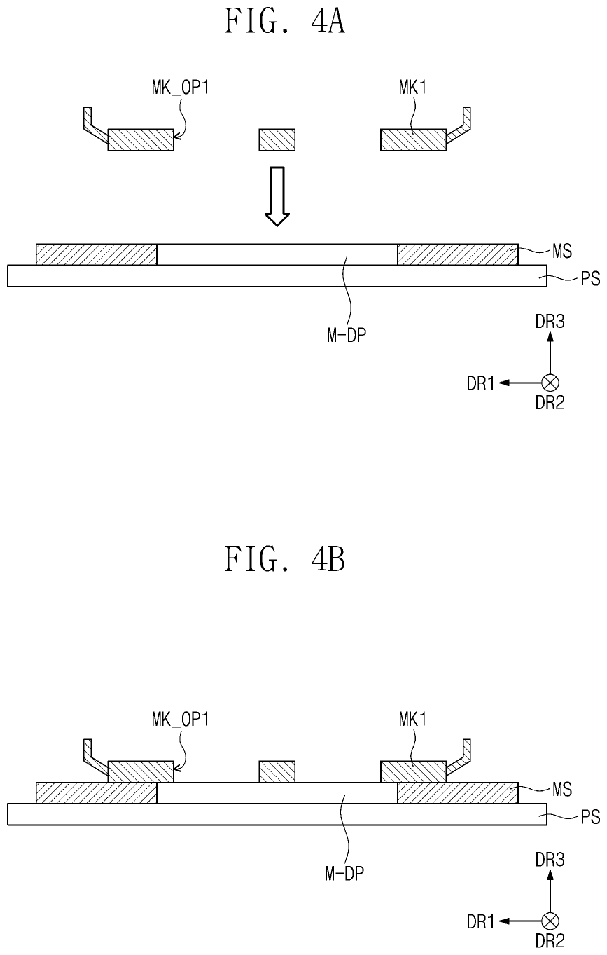

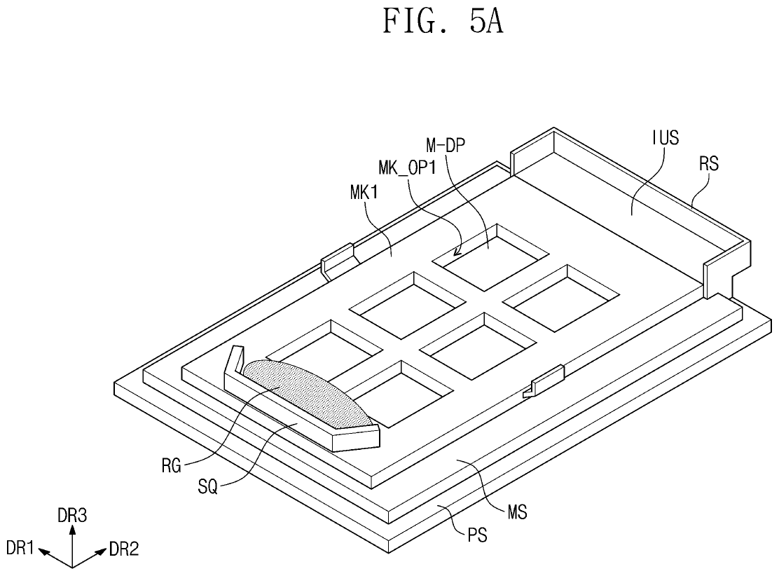

The applying unit AU may perform the first applying process to form the cover layer CL (refer to FIG. 2) using the first mask MK1 (refer to FIG. 3A), and the cleaning unit CU may perform the first cleaning process to clean the second mask MK2 (refer to FIG. 3A). Hereinafter, the first applying process will be described with reference to FIGS. 4A to 7B.

FIGS. 4A and 4B are cross-sectional views illustrating a process of placing the first mask MK1 on the mask stage MS according to an embodiment of the present disclosure. A process of placing the first mask MK1 on the mask stage MS will be described with reference to FIGS. 4A and 4B.

The first mask MK1 may be seated on the mask stage MS while the mother substrate M-DP is disposed in the mask stage MS. In this case, the display panels DP (refer to FIG. 2) formed in the mother substrate M-DP may be aligned with the first mask openings MK_OP1 defined through the first mask MK1. The mother substrate M-DP may be disposed on the panel stage PS to allow the rear surface of the panel stage PS to face the first mask MK1.

FIGS. 5A to 5C are perspective views illustrating a first squeezing process according to an embodiment of the present disclosure.

The process of applying the resin RG to the one side of the first mask MK1 will be described with reference to FIG. 5A, and then, the first squeezing process will be described with reference to FIGS. 5B and 5C.

Referring to FIG. 5A, the squeeze SQ may be disposed at the one side of the upper surface of the first mask MK1. The resin RG may be applied to the upper surface of the first mask MK1 and may be collected on the one side of the first mask MK1 by the squeeze SQ. In an embodiment, the upper surface of the first mask MK1 may face the third direction DR3.

The resin stage RS may be disposed at the other side of the first mask MK1. Although not shown in the drawing, before the first squeezing process, the resin stage RS may be disposed spaced apart from the first mask MK1 with first mask openings MK_OP1 interposed therebetween in second direction DR2. The resin stage RS may provide a space where a portion of the resin RG pushed by the squeeze SQ stays.

As an example, the resin stage RS may have a structure in which a portion facing towards the first mask MK1 and a portion facing towards the third direction DR3 are opened and other portions are closed, however, this is merely an example. According to an embodiment, the resin stage RS may have various structures as long as the resin stage RS provides the space where the portion of the resin RG pushed by the squeeze SQ stays. An inner-upper surface IUS of the resin stage RS may be substantially flush with the upper surface of the first mask MK1, and there is no step difference between the inner-upper surface IUS of the resin stage RS and the upper surface of the first mask MK1.

Referring to FIG. 5B, the resin RG may be pushed to the second direction DR2 by the squeeze SQ in the first squeezing process and may be disposed in the corresponding first mask openings MK_OP1.

The squeeze SQ may move from the one side (i.e., the side opposite to a side adjacent to the resin stage RS) of the first mask MK1 to the resin stage RS, and thus, the resin RG may be sequentially disposed in the first mask openings MK_OP1. Referring to FIG. 5C, when the first squeezing process is performed, the squeeze SQ may reach the resin stage RS. In this case, the resin RG collected on the resin stage RS after the first squeezing process may be defined as a stage resin RG_S. On or in the first mask MK1, not only a filling resin RG_1 filled in the first mask opening MK_OP1 but also a remaining resin RG_2 remaining on the first mask MK1 without being filled in the first mask opening MK_OP1 may exist.

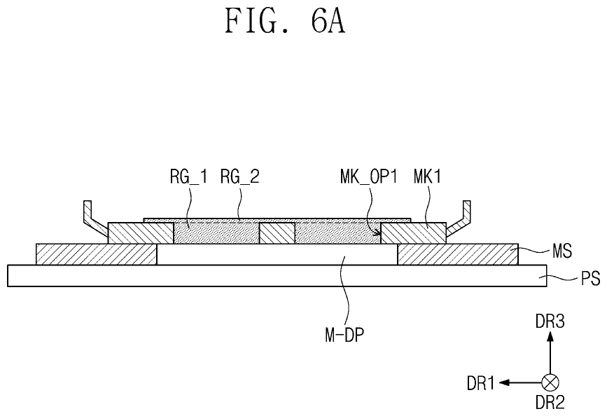

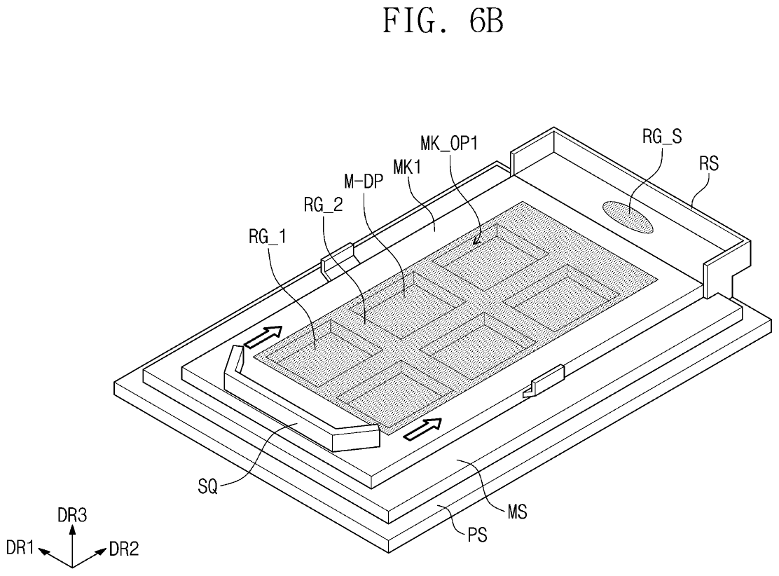

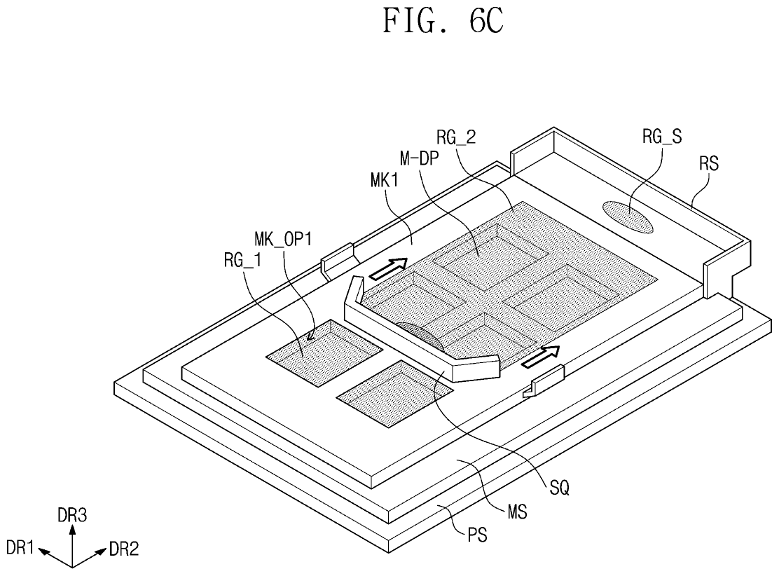

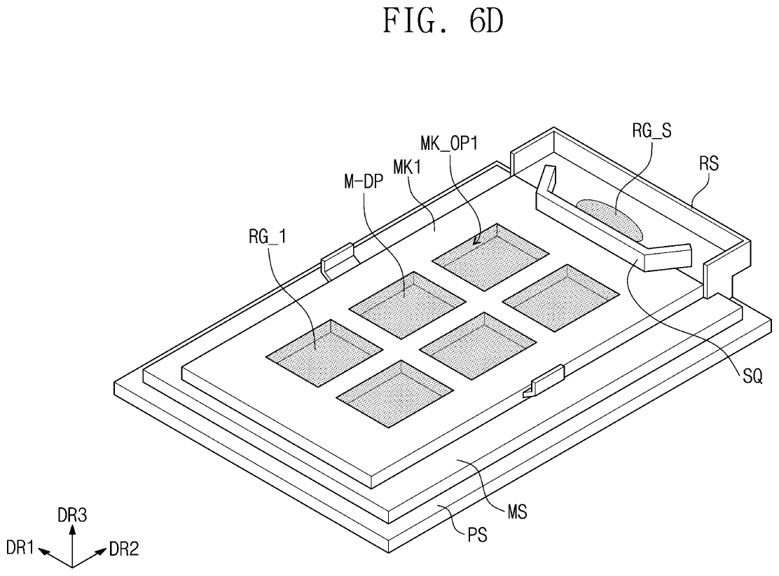

FIGS. 6A to 6D are views illustrating a processing of removing the remaining resin according to an embodiment of the present disclosure. The process of removing the remaining resin will be described with reference to FIGS. 6A to 6D.

FIG. 6A is a cross-sectional view illustrating the filling resin RG_1 and the remaining resin RG_2, which are formed after the first squeezing process.

When the first mask MK1 is separated from the mother substrate M-DP in the state where the remaining resin RG_2 is formed, the remaining resin RG_2 formed on the upper surface of the first mask MK1 and the remaining resin RG_2 formed on the filling resin RG_1 may be cracked, and as a result, the cover layer CL (refer to FIG. 2) may not be formed uniformly. Accordingly, the remaining resin RG_2 is desirable to be removed.

FIGS. 6B to 6D are perspective views illustrating the process of removing the remaining resin RG_2 formed on the upper surface of the first mask MK1.

To remove the remaining resin RG_2, the operation of moving the squeeze SQ, which is the same as the operation performed in the first squeezing process, may be repeated after replacing the squeeze SQ at the one side of the first mask MK1.

Accordingly, the remaining resin RG_2 formed on the upper surface of the first mask MK1 may be pushed to the second direction DR2 by the squeeze SQ, and the remaining resin RG_2 may be collected on the resin stage RS. In this case, since the filling resin RG_1 is already in the first mask opening MK_OP1, the filling resin RG_1 in the first mask opening MK_OP1 may not be removed by the squeeze SQ.

The removing process of the remaining resin may be repeatedly performed several times until the remaining resin RG_2 is removed from the first mask MK1. In this case, an amount of the stage resin RG_S collected on the resin stage RS may increase.

The stage resin RG_S collected on the resin stage RS may be used in an additional squeezing process performed later.

According to another embodiment, in a case where the filling resin RG_1 is not sufficiently formed in the first squeezing process, an additional squeezing process may be performed. The additional squeezing process may be a process of moving the squeeze SQ from the resin stage RS to the one side of the first mask MK1 in a direction opposite to the second direction DR2. In this case, the stage resin RG_S collected on the resin stage RS may be rearranged in the first mask opening MK_OP1.

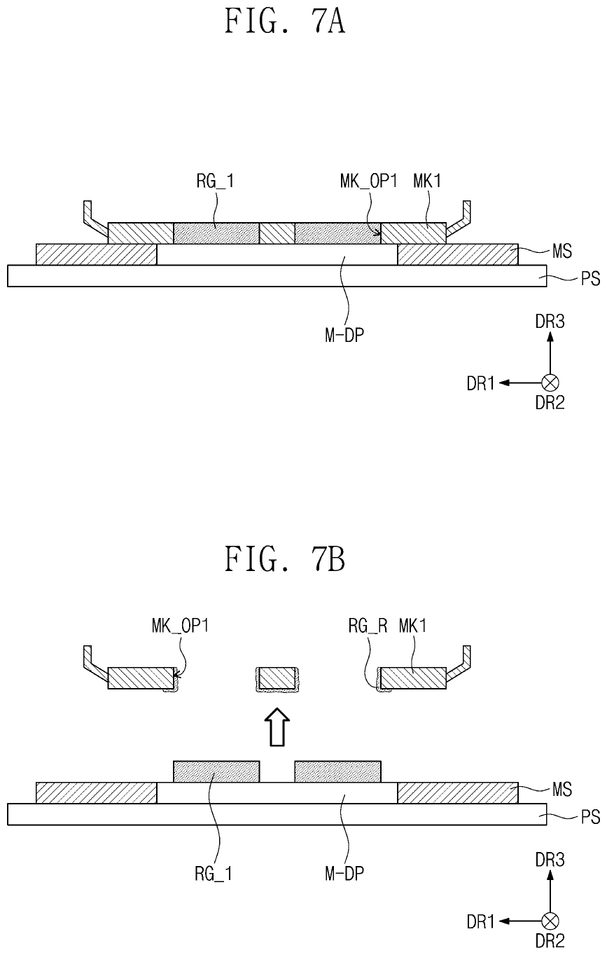

FIGS. 7A and 7B are cross-sectional views illustrating a process of separating the first mask MK1 from the applying unit AU after the first applying process is finished.

Referring to FIG. 7A, the filling resin RG_1 may be formed as the cover layer CL described with reference to FIG. 2 after being cured.

Referring to FIG. 7B, after the filling resin RG_1 is cured, the first mask MK1 may be separated from the mother substrate M-DP.

When the first mask MK1 is separated from the mother substrate M-DP, a residual resin RG_R may remain on the first mask MK1.

The residual resin RG_R may be attached to the inner side surface of the first mask MK1, which defines the first mask opening MK_OP1, and the lower surface of the first mask MK1, which is adjacent to the inner side surface of the first mask MK1. The residual resin RG_R may be defined as a portion of the filling resin RG_1, which remains on the first mask MK1 due to an adhesive force with the first mask MK1.

When the process of forming the cover layer CL (refer to FIG. 2) is performed again using the first mask MK1 on which the residual resin RG_R remains, the residual resin RG_R may disturb the applying process. As an example, the residual resin RG_R may disturb the applying process between the first mask MK1 and the display panel DP. In addition, the residual resin RG_R may fall on the display panel DP and may cause excessive applying of the resin RG (refer to FIG. 5B). Accordingly, a cleaning process for the residual resin RG_R is desirable.

FIGS. 8A to 8C are cross-sectional views illustrating the first cleaning process according to an embodiment of the present disclosure.

A first immersing process will be described with reference to FIG. 8A.

In the present disclosure, the second mask MK2 may be defined as a mask where the residual resin RG_R remains on an inner side surface and a lower surface of the mask after the processes described with reference to FIGS. 4A to 7B are performed. That is, the second mask MK2 to be described with reference to FIGS. 8A to 8C may be the mask used in the applying process performed in the applying unit AU (refer to FIG. 3B).

The residual resin RG_R may exist on the second mask MK2 after the applying process is completed. The second mask MK2 may be placed on the bath BT by the rotation driver DR (refer to FIG. 3A) and may move into the bath BT by the connector LK. Accordingly, the second mask MK2 may be immersed into the cleaning solution SL.

A first ultrasonic cleaning process will be described with reference to FIG. 8B.

While the second mask MK2 is immersed in the cleaning solution SL, the second mask MK2 may be cleaned with the ultrasonic generator VB firstly and may be cleaned with the brush BR secondly.

The cleaning solution SL may include a material that dissolves the residual resin RG_R. As an example, the cleaning solution SL may include at least one of N-Methyl-2-pyrrolidone (NMP) and an acidic substance that dissolves an organic material.

The vibration generated by the ultrasonic generator VB may be applied to the cleaning solution SL. The cleaning solution SL may be vibrated, and thus, impacts may be applied to the residual resin RG_R remaining on the second mask MK2. Due to the impacts, the residual resin RG_R may be separated from the second mask MK2 or a crack may occur in the residual resin RG_R, and thus, the cleaning solution SL may permeate into the residual resin RG_R more easily. Accordingly, the residual resin RG_R may be effectively removed.

The cleaning unit CU may include at least one brush BR disposed in the bath BT and rotating in a predetermined direction. The first cleaning process may further include rotating the brush BR to clean the second mask MK2. As the brush BR rotates in the bath BT, a whirlpool may be created in the cleaning solution SL.

In the first cleaning process, the brush BR may be disposed in a second mask opening MK_OP2 defined through the second mask MK2.

According to an embodiment, the brush BR may be spaced apart from the inner side surface of the second mask MK2, which defines the second mask opening MK_OP2. Accordingly, the residual resin RG_R remaining on the second mask MK2 may be effectively removed by the whirlpool of the cleaning solution SL, which is created by the rotation of the brush BR.

In a case where the brush BR is in contact directly with the second mask MK2 in the cleaning process, the second mask MK2 may be contaminated or deformed. Accordingly, it is desirable for the brush BR to rotate and move near the second mask MK2 without directly contacting the second mask MK2. However, in a case where the second mask MK2 has sufficient rigidity not to be deformed due to a material of the second mask MK2, or in a case where the brush BR is soft enough not to damage the second mask MK2 even when the brush BR touches the second mask MK2, the brush BR may be directly in contact with the second mask MK2 while cleaning a surface of the second mask MK2.

A first taking-out process will be explained with reference to FIG. 8C.

The second mask MK2 from which the residual resin RG_R is removed through the cleaning process may move outside of the bath BT by the rotation driver DR (refer to FIG. 3A). The second mask MK2 cleaned through the cleaning process may move to the applying unit AU by the rotation driver DR (refer to FIG. 3A), and then, the applying process may be newly performed on a new mother substrate.

According to the present disclosure, the first applying process and the first cleaning process may be substantially simultaneously performed. In the present disclosure, the expression “two processes are performed substantially simultaneously” means that at least a portion of each of the two processes overlap each other in time and is not be limited to start and end times of the two processes being completely matched.

Although not shown in the views, the same/similar contents as the first cleaning step described with reference to FIGS. 8A to 8C may be applied to the second cleaning step.

That is, the second cleaning step includes a second immersing process in which the first mask is immersed in the cleaning solution, a second ultrasonic cleaning process in which the first mask is washed with the ultrasonic waves, and a second taking-out process in which the first mask out of the cleaning solution. The duplicated content about the second cleaning step is omitted.

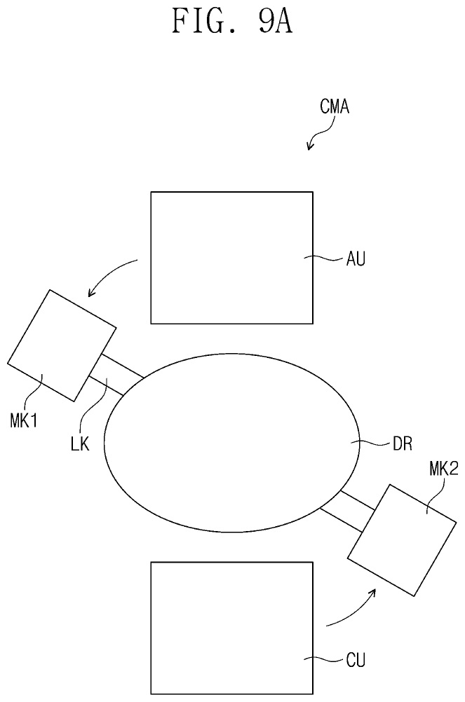

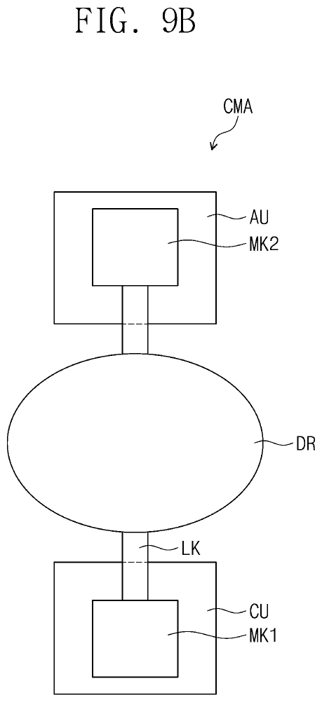

FIGS. 9A and 9B are views schematically illustrating a rotating process according to an embodiment of the present disclosure. The rotating process will be described with reference to FIGS. 9A and 9B.

Referring to FIG. 9A, the rotation driver DR may provide the power to rotate the connector LK, and accordingly, the process of rotating the first mask MK1 and the second mask MK2, which are connected to the connector LK, may be performed.

When both the first applying process in the applying unit AU and the first cleaning process in the cleaning unit CU are completed, the rotation driver DR operates.

The first mask MK1 and the second mask MK2 may be connected to the connector LK of the rotation driver DR. When the rotation driver DR provides the power to the connector LK and the connector LK rotates, the first mask MK1 and the second mask MK2 connected to the connector LK may rotate. The position of the first mask MK1 and the position of the second mask MK2 may be changed by the rotation. Referring to FIG. 9B, the position of the first mask MK1 and the position of the second mask MK2 may be changed when the rotating process is completed.

When the rotating process is completed, the second mask MK2 that is cleaned through the cleaning process may be placed on the applying unit AU, and the first mask MK1 that is used in the applying process may be placed on the cleaning unit CU.

The second applying process may be performed in the applying unit AU to form the cover layer CL on the rear surface of the second mother substrate M-DP using the second mask MK2.

In the present disclosure, the second applying process may be performed in the same way as the first applying process described with reference to FIGS. 3A to 7B. Accordingly, the process of forming the cover layer CL (refer to FIG. 2) may be performed on a new mother substrate M-DP (refer to FIG. 3A) disposed in the applying unit AU (refer to FIG. 3B).

The cleaning unit CU may perform the second cleaning process to clean the first mask MK1.

In the present disclosure, the second cleaning process may be performed in the same way as the first cleaning process described with reference to FIGS. 8A to 8C. Accordingly, the cleaning process may be performed to clean the first mask MK1 disposed in the cleaning unit CU (refer to FIG. 8A).

According to the present disclosure, the second applying process and the second cleaning process may be substantially simultaneously performed.

Therefore, since the second applying process and the second cleaning process may be performed simultaneously, the yield of the process to form the cover layer CL (refer to FIG. 2) may be improved, and a time consumed to separately perform the applying process and the cleaning process may be reduced. As a result, a process time for the cover layer manufacturing method may effectively decrease.

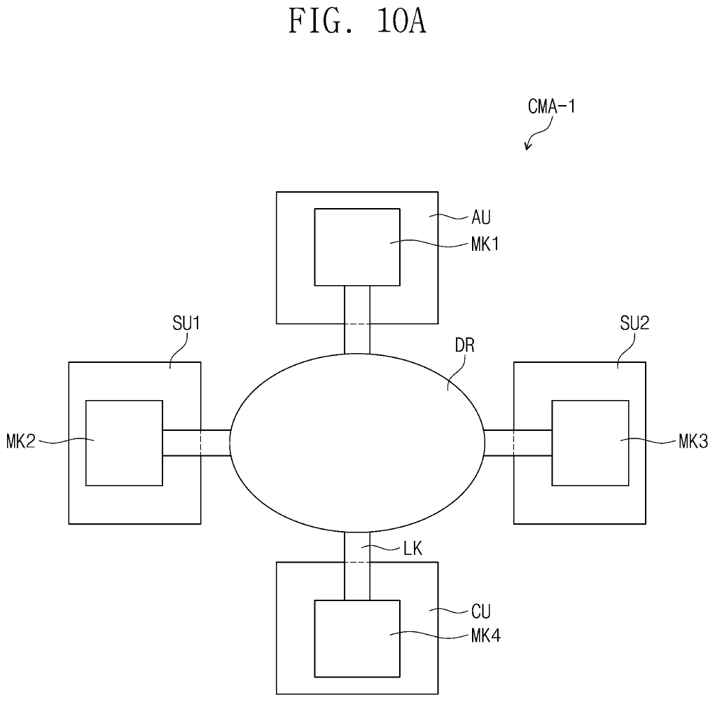

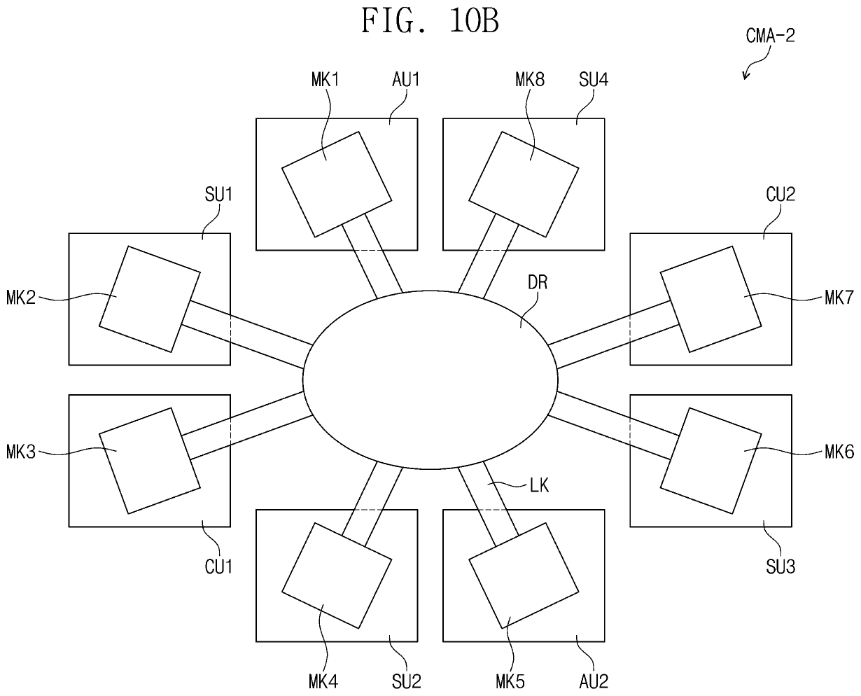

FIG. 10A is a view schematically illustrating a cover layer manufacturing apparatus CMA-1 according to an embodiment of the present disclosure.

The cover layer manufacturing apparatus CMA-1 may include a plurality of masks. As an example, the number of the masks may be four.

The cover layer manufacturing apparatus CMA-1 may include an applying unit AU, a first standby unit SU1, a cleaning unit CU, and a second standby unit SU2.

A first mask MK1 may be disposed on the applying unit AU, a second mask MK2 may be disposed on the first standby unit SU1, a third mask MK3 may be disposed on the second standby unit SU2, and a fourth mask MK4 may be disposed on the cleaning unit CU.

In the present embodiment, the first mask MK1 may be a mask to be used in a first applying process, the second mask MK2 may be a mask that is on standby for a cleaning process after being used in the applying process, the third mask MK3 may be a mask to be cleaned through a first cleaning process, and the fourth mask MK4 may be a mask that is on standby for the applying process after being cleaned through the cleaning process.

When the first applying process and the first cleaning process are completed, a rotation driver DR may perform a rotating process to change a position of the first mask MK1, a position of the second mask MK2, a position of the third mask MK3, and a position of the fourth mask MK4. When the rotating process is completed, the third mask MK3 may be disposed in the applying unit AU, the first mask MK1 may be disposed in the first standby unit SU1, the fourth mask MK4 may be disposed in the second standby unit SU2, and the second mask MK2 may be disposed in the first cleaning unit CU.

The applying unit AU may perform a second applying process using the third mask MK3 to form a cover layer CL on a rear surface of a display panel DP. Accordingly, even in a case where the total number of the applying unit AU and the cleaning unit CU is smaller than the total number of the masks, since the cover layer manufacturing apparatus CMA-1 includes the first standby unit SU1 and the second standby unit SU2, the first applying process and the second applying process may be sequentially performed in time.

FIG. 10B is a view schematically illustrating a cover layer manufacturing apparatus CMA-2 including eight masks according to an embodiment of the present disclosure.

Referring to FIG. 10B, a first applying unit AU1, a first standby unit SU1, a first cleaning unit CU1, a second standby unit SU2, a second applying unit AU2, a third standby unit SU3, a second cleaning unit CU2, and a fourth standby unit SU4 may be arranged in a counterclockwise direction.

After completing the process in each unit, the masks disposed in the units, respectively, may be rotated in the counterclockwise direction. In this case, since the first to second applying units AU1 to AU2 and the first to second cleaning units CU1 and CU2 are alternately arranged with each other, the mask that has gone through the applying process may proceed to the cleaning process, and the mask that has gone through the cleaning process may proceed to the applying process. Since the subsequent processes are substantially the same as those in the case where the number of masks is two or four, details of the same processes will not be repeated.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present invention shall be determined according to the attached claims.

What is claimed is:

1. A method of manufacturing a cover layer, comprising:
a first applying process, which forms a first cover layer on a rear surface of a mother substrate using a first mask in an applying unit;
a first cleaning process, which cleans a second mask in a cleaning unit;
a rotating process, which changes a position of the first mask and a position of the second mask using a rotation driver;
a second applying process, which forms a second cover layer on a rear surface of another mother substrate using the second mask in the applying unit; and
a second cleaning process, which cleans the first mask in the cleaning unit,
wherein the first applying process and the first cleaning process are substantially simultaneously performed, and the second applying process and the second cleaning process are substantially simultaneously performed.

2. The method of claim 1, wherein the applying unit comprises:
a panel stage;
a mask stage disposed on the panel stage;
a squeeze disposed on the first mask; and
a resin stage disposed at one side of the mask stage,
wherein the first mask is provided with a first mask opening defined therethrough to expose the rear surface of the mother substrate, and
wherein the first applying process comprises:
placing the first mask on the mask stage;
applying a resin on one side of the first mask; and
a first squeezing process, which moves the squeeze in a direction from the one side of the first mask toward the resin stage to place the resin in the first mask opening.

3. The method of claim 2, further comprising a remaining resin removing process, which moves the squeeze in the direction from the one side of the first mask toward the resin stage to remove a remaining resin disposed on an upper surface of the first mask after the first squeezing process.

4. The method of claim 2, further comprising an additional squeezing process, which moves the squeeze in a direction from the resin stage toward the one side of the first mask to rearrange a stage resin collected on the resin stage in the first mask opening after the first squeezing process.

5. The method of claim 4, wherein the second mask is provided with a second mask opening defined therethrough to expose the rear surface of the another mother substrate, and the second applying process comprises:
placing the second mask on the mask stage;
applying a resin on one side of the second mask; and
a second squeezing process, which moves the squeeze in a direction from the one side of the second mask toward the resin stage to place the resin in the second mask opening.

6. The method of claim 1, wherein the cleaning unit comprises:
a bath accommodating a cleaning solution; and
an ultrasonic generator disposed in the bath and generating an ultrasonic wave in the cleaning solution.

7. The method of claim 6, wherein the first cleaning process further comprises:
a first immersing process, which immerses the second mask into the cleaning solution;
a first ultrasonic cleaning process, which cleans the second mask using the ultrasonic wave; and
a first taking-out process, which takes the second mask out of the cleaning solution, and wherein the second cleaning process further comprises:
a second immersing process, which immerses the first mask into the cleaning solution;
a second ultrasonic cleaning process, which cleans the first mask using the ultrasonic wave; and
a second taking-out process, which takes the first mask out of the cleaning solution.

8. The method of claim 7, wherein the cleaning unit further comprises at least one brush disposed in the bath and rotating in a predetermined direction,
the first cleaning process further comprises rotating the at least one brush to clean the second mask, and
the second cleaning process further comprises rotating the at least one brush to clean the first mask.

9. The method of claim 8, wherein the at least one brush is disposed spaced apart from the second mask in an opening defined through the second mask in the first cleaning process,
the second mask is cleaned by a whirlpool of the cleaning solution, which is generated by the rotation of the at least one brush in the first cleaning process,
the at least one brush is disposed spaced apart from the first mask in an opening defined through the first mask in the second cleaning process, and
the first mask is cleaned by a whirlpool of the cleaning solution, which is generated by the rotation of the at least one brush in the second cleaning process.

10. A method of manufacturing a cover layer, comprising:
a first applying process, which forms a first cover layer on a rear surface of a mother substrate using a first mask in an applying unit;
a first standby process in which a second mask used in the applying unit prior to the first applying process is on standby in a first standby unit;
a first cleaning process, which cleans a third mask in a cleaning unit;
a second standby process in which a fourth mask cleaned in the cleaning unit prior to the first cleaning process is on standby in a second standby unit; and
a rotating process, which changes a position of the first mask, a position of the second mask, a position of the third mask, and a position of the fourth mask using a rotation driver,
wherein the first applying process and the first cleaning process are substantially simultaneously performed.

11. The method of claim 10, wherein, after the rotating process, the first mask is placed in the first standby unit, and the third mask is placed in the second standby unit.

12. The method of claim 11, further comprising:
a second applying process, which forms a second cover layer on a rear surface of another mother substrate using the fourth mask in the applying unit after the rotating process; and
a second cleaning process, which cleans the second mask using the cleaning unit after the rotating process,
wherein the second applying process and the second cleaning process are substantially simultaneously performed.

13. An apparatus of manufacturing a cover layer, comprising:
an applying unit comprising a panel stage and a mask stage disposed on the panel stage, wherein a mother substrate is disposed in an opening of the mask stage and a front surface of the mother substrate faces the panel stage;
a cleaning unit comprising a bath configured to accommodate a cleaning solution and an ultrasonic generator configured to generate an ultrasonic wave in the cleaning solution;
a first mask disposed on the mask stage;
a second mask disposed in the bath; and
a rotation driver,
wherein the applying unit is configured to form a cover layer on a rear surface of the mother substrate using the first mask, the second mask is configured to be cleaned in the cleaning unit while the cover layer is formed, and the first mask and the second mask are each provided with an opening defined therethrough.

14. The apparatus of claim 13, further comprising a standby unit in which a mask used in the applying unit or a mask cleaned in the cleaning unit is on standby.

15. The apparatus of claim 14, wherein the applying unit, the cleaning unit, the standby unit, the first mask, the second mask, and the mask in the standby unit are each provided one or more,
wherein a total number of the first mask, the second mask, and the mask in the standby unit is equal to a total number of the applying unit, the cleaning unit, and the standby unit.

16. The apparatus of claim 13, wherein the applying unit further comprises a resin stage and a squeeze.

17. The apparatus of claim 13, wherein the cover layer comprises a light-absorbing material.

18. The apparatus of claim 13, further comprising at least one brush disposed in the bath, wherein the at least one brush rotates to generate a whirlpool in the cleaning solution.

19. The apparatus of claim 18, wherein the at least one brush is spaced apart from an inner side surface defining the opening of the second mask.

20. The apparatus of claim 13, wherein the rotation driver is connected to each of the first mask and the second mask by a connector.
